(19) United States
(12) Patent Application Publication
(10) Pub. No.: US 2023/0223165 A1
(43) Pub. Date: Jul. 13, 2023

(54) ELECTRODE OR WIRING, ELECTRODE PAIR, AND METHOD FOR PRODUCING ELECTRODE OR WIRING

(71) Applicant: Murata Manufacturing Co., Ltd., Nagaokakyo-shi (JP)

(72) Inventors: Yasunori HIOKI, Nagaokakyo-shi (JP); Kazuari SASAKI, Kyoto (JP); Shun SAKAIDA, Nagaokakyo-Shi (JP)

(21) Appl. No.: 18/182,794

(22) Filed: Mar. 13, 2023

Related U.S. Application Data
(63) Continuation of application No. PCT/JP2021/033929, filed on Sep. 15, 2021.

(30) Foreign Application Priority Data
Sep. 17, 2020 (JP) 2020-156698

(51) Int. Cl. H01B 1/22; H01B 1/02; H05K 1/09; B22F 5/00

(52) U.S. Cl. CPC H01B 1/22; H01B 1/02; H01B 1/026; H05K 1/095; H05K 1/09; B22F 5/00; H05K 2201/0209; H05K 2201/0215; H05K 2201/0245

(57) ABSTRACT

An electrode or wiring, an electrode pair, and a method for manufacturing the electrode or wiring. The electrode or wiring includes: particles of a layered material including one or more layers; and metal particles or a sintered metal. The one or plural layers include a layer body represented by MₘXₙ, wherein M is at least one metal belonging to group 3, 4, 5, 6, or 7, X is a carbon atom, a nitrogen atom, or a combination thereof, n is 1-4, and m is greater than n and at most 5, and a modification or terminal T (T being at least one of a hydroxyl group, a fluorine atom, a chlorine atom, an oxygen atom, and a hydrogen atom) is present on the surface of the layer body.

### CROSS REFERENCE TO RELATED APPLICATIONS

The present application is a continuation of International application No. PCT/JP2021/033929, filed Sep. 15, 2021, which claims priority to Japanese Patent Application No. 2020-156698, filed Sep. 17, 2020, the entire contents of each of which are incorporated herein by reference.

### FIELD OF THE INVENTION

The present invention relates to an electrode or wiring, an electrode pair, and a method for producing an electrode or wiring.

### BACKGROUND OF THE INVENTION

In an electronic component such as an inductor, there is a problem that ion migration occurs due to ionization of a material constituting the electronic component, moisture from the outside under high humidity, and the like. When the ion migration occurs, a defect such as a short circuit occurs. For the purpose of suppressing defects caused by external moisture, for example, Patent Document 1 discloses an inorganic anion exchanger and an epoxy resin composition for electronic component sealing using the same. In particular, it is shown that by treating and coating a predetermined hydrotalcite compound with a metal oxide, an inorganic anion exchanger having low hygroscopicity and excellent anion exchange performance can be obtained. Patent Document 2 discloses that a triazine compound which is an organic compound is dissolved or uniformly dispersed in a predetermined polymer to prevent migration of an electronic component or the like.
Patent Document 1: JP-A-2005-1902
Patent Document 2: JP-A-2014-210732

### SUMMARY OF THE INVENTION

Incidentally, the electrode or wiring constituting the electronic component is required to have high conductivity as well as the suppression of the ion migration. However, since both the inorganic compound disclosed in Patent Document 1 and the organic compound disclosed in Patent Document 2 exhibit insulating properties, the conductivity decreases when the inorganic compound and the organic compound are blended in an electrode. The present invention has been made in view of the above circumstances, and an object of the present invention is to provide an electrode or wiring, an electrode pair, and a method for producing an electrode or wiring, in which ion migration is suppressed under high humidity and conductivity is excellent.

According to one gist of the present invention, there is provided an electrode or wiring including:

particles of a layered material including one or plural layers; and

metal particles or sintered metal,

wherein the one or plural layers includes a layer body represented by:

ₘXₙ

wherein M is at least one metal of Group 3, 4, 5, 6, or 7,

X is a carbon atom, a nitrogen atom, or a combination thereof,

n is 1 to 4, and

m is more than n and 5 or less, and

a modifier or terminal T exists on a surface of the layer body, wherein T is at least one selected from the group consisting of a hydroxyl group, a fluorine atom, a chlorine atom, an oxygen atom, or a hydrogen atom.

According to another gist of the present invention, there is provided an electrode pair including:

an anode; and

a cathode,

wherein at least one of the anode and the cathode include:

particles of a layered material including one or plural layers, and

metal particles or sintered metal,

the one or plural layers includes a layer body represented by:

MₘXₙ

wherein M is at least one metal of Group 3, 4, 5, 6, or 7,

X is a carbon atom, a nitrogen atom, or a combination thereof,

n is 1 to 4, and

m is more than n and 5 or less, and

a modifier or terminal T exists on a surface of the layer body, wherein T is at least one selected from the group consisting of a hydroxyl group, a fluorine atom, a chlorine atom, an oxygen atom, or a hydrogen atom.

According to still another gist of the present invention, there is provided a method for producing an electrode or wiring, the method including:

(a1) kneading particles of a layered material including one or plural layers, metal particles, and a resin to prepare a mixture,

the one or plural layers including a layer body represented by:

MₘXₙ

wherein M is at least one metal of Group 3, 4, 5, 6, or 7,

X is a carbon atom, a nitrogen atom, or a combination thereof,

n is 1 to 4, and

m is more than n and 5 or less, and

a modifier or terminal T exists on a surface of the layer body,

wherein T is at least one selected from the group consisting of a hydroxyl group, a fluorine atom, a chlorine atom, an oxygen atom, or a hydrogen atom, and

a blending ratio of the particles of the layered material in the mixture is 0.1 mass % to 20 mass % with respect to the metal particles; and

(b1) drying the mixture to obtain an electrode or wiring.

According to still another gist of the present invention,

there is provided a method for producing an electrode or wiring, the method including:

(a2) kneading a formulation containing particles of a layered material including one or plural layers and metal particles to prepare a mixture,

the one or plural layers including a layer body represented by:

MₘXₙ

wherein M is at least one metal of Group 3, 4, 5, 6, or 7,

X is a carbon atom, a nitrogen atom, or a combination thereof,

n is 1 to 4, and

m is more than n and 5 or less, and

a modifier or terminal T exists on a surface of the layer body,

wherein T is at least one selected from the group consisting of a hydroxyl group, a fluorine atom, a chlorine atom, an oxygen atom, or a hydrogen atom, and

a blending ratio of the particles of the layered material in the mixture is 0.1 mass % to 20 mass % with respect to the metal particles;

(b2) molding and drying the mixture to obtain a molded product; and

(c) firing the molded product at a sinterable temperature.

According to the present invention, there is provided an electrode or wiring including particles of a predetermined layered material (also referred to as “MXene” in the present specification) and metal particles or a sintered metal, the electrode or wiring including MXene, suppressing ion migration even under high humidity, and having excellent conductivity. In addition, according to the present invention, the electrode or wiring can be produced by preparing a mixture by kneading particles of a predetermined layered material (particles of MXene), metal particles, and a resin, setting a blending ratio of the particles of the layered material in the mixture to 0.1 mass % to 20 mass % with respect to the metal particles, and drying the mixture.

### BRIEF DESCRIPTION OF THE DRAWINGS

FIG. 1 is a schematic cross-sectional view illustrating an electrode or wiring according to one embodiment of the present invention.

FIG. 2 is a schematic cross-sectional view illustrating an electrode or wiring according to another embodiment of the present invention.

FIGS. 3(a) and 3(b) are schematic cross-sectional views illustrating MXene that is a layered material that can be used in a conductive composite material according to one embodiment of the present invention.

FIG. 4 is a schematic view illustrating a mechanism of occurrence of Ag ion migration.

FIG. 5 is a photograph illustrating an evaluation result of ion migration of a comparative example.

FIG. 6 is a photograph illustrating an evaluation result of ion migration in an example.

FIG. 7 is a photograph illustrating an evaluation result of ion migration of another comparative example.

FIG. 8 is a photograph illustrating an evaluation result of ion migration in another example.

### DETAILED DESCRIPTION OF THE INVENTION

### Embodiment 1: Electrode or Wiring

The electrode or wiring in the embodiment of the present invention contains particles of a predetermined layered material and metal particles or a sintered metal, so that ion migration is suppressed even under high humidity, and an electrode or wiring having excellent conductivity can be realized.

Hereinafter, an electrode or wiring in the embodiment of the present invention will be described in detail, but the electrode or wiring of the present invention is not limited to such an embodiment.

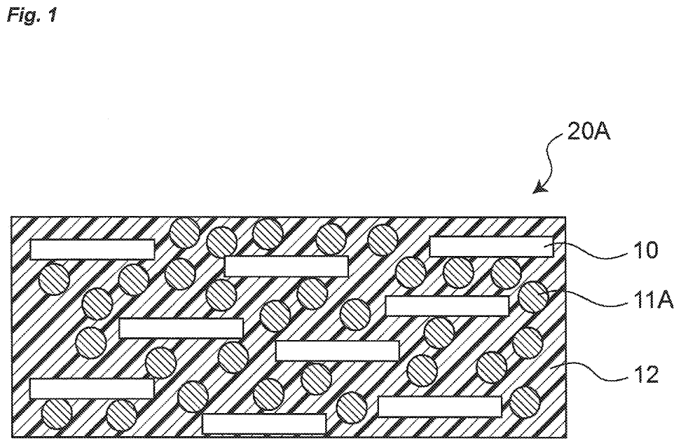

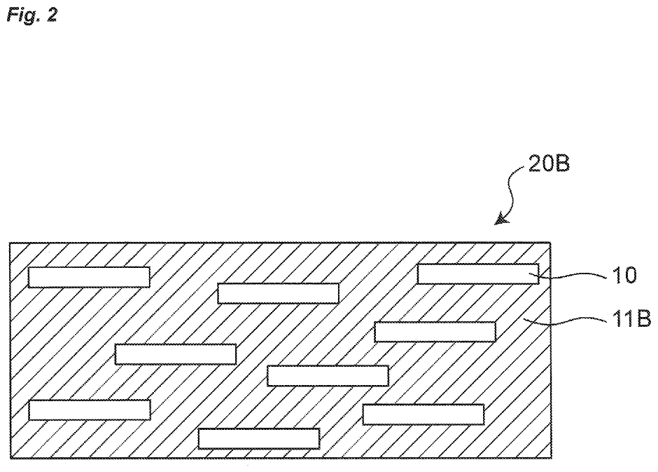

Referring to FIG. 1, examples of one electrode or wiring of the present embodiment include an electrode or wiring 20A formed of a composite material containing particles 10 of a predetermined layered material, metal particles 11A, and a resin 12. Referring to FIG. 2, examples of another electrode or wiring of the present embodiment include an electrode or wiring 20B formed of a sintered body containing particles 10 of a predetermined layered material and a sintered metal 11B. The composite material or the sintered body is a material that easily forms an electrode or wiring.

First, particles of a predetermined layered material included in both the electrode or wiring 20A and the electrode or wiring 20B will be described.

The particles of the predetermined layered material in the present embodiment are MXene (particles), and are defined as follows.

The particles of the layered material including one or plural layers, the one or plural layers including a layer body represented by:

MₘXₙ

wherein M is at least one metal of Group 3, 4, 5, 6, or 7, and can comprise at least one selected from the group consisting of so-called early transition metals, for example, Sc, Ti, Zr, Hf, V, Nb, Ta, Cr, Mo, or Mn,

X is a carbon atom, a nitrogen atom, or a combination thereof,

n is 1 to 4, and

m is more than n and 5 or less

(the layer body can have a crystal lattice in which each X is located in the octahedral array of M), and a modifier or terminal T exists on a surface of the layer body (more specifically, on at least one of two surfaces, facing each other, of the layer body), wherein T is at least one selected from the group consisting of a hydroxyl group, a fluorine atom, a chlorine atom, an oxygen atom, or a hydrogen atom (the layered material can be understood as a layered compound and also represented by “MₘXₙTₓ”, wherein x is any number and traditionally z or s may be used instead of x). Typically, n can be 1, 2, 3, or 4.

In the above formula of MXene, M is preferably at least one selected from the group consisting of Ti, Zr, Hf, V, Nb, Ta, Cr, Mo, or Mn, and more preferably at least one selected from the group consisting of Ti, V, Cr, or Mo.

In the above formula of MXene, M is more preferably Ti, X is a carbon atom, or a carbon atom and a nitrogen atom. As the layer body, at least one selected from the group consisting of Ti₃C₂, Ti₃CN, or Ti₂C is more preferable and Ti₃C₂ is particularly preferable. When MXene having the layer body is used, high conductivity can be secured.

Such MXene can be synthesized by selectively etching (removing and optionally layer-separating) A atoms (and optionally parts of M atoms) from a MAX phase. The MAX phase is represented by the following formula:

MₘAXₙ

(wherein M, X, n, and m are as described above, and A is at least one element of Group 12, 13, 14, 15, or 16, is usually a Group A element, typically Group IIIA and Group IVA, more specifically, may include at least one selected from the group consisting of Al, Ga, In, Tl, Si, Ge, Sn, Pb, P, As, S, or Cd, and is preferably Al), and has a crystal structure in which a layer formed of A atoms is located between two layers (each X may have a crystal lattice located within an octahedral array of M) represented by MₘXₙ. Typically, in the case of m=n+1, the MAX phase has a repeating unit in which one layer of X atoms is disposed between the layers of M atoms of n+1 layers (these layers are also collectively referred to as “MₘXₙ layer”), and a layer of A atoms (“A atom layer”) is disposed as a next layer of the (n+1)th layer of M atoms; however, the present invention is not limited thereto. By selectively etching (removing and optionally layer-separating) the A atoms (and optionally a part of the M atoms) from the MAX phase, the A atom layer (and optionally a part of the M atoms) is removed, and a hydroxyl group, a fluorine atom, a chlorine atom, an oxygen atom, a hydrogen atom, and the like existing in an etching liquid (usually, but not limited to, an aqueous solution of a fluorine-containing acid is used) are modified on the exposed surface of the MₘXₙ layer, thereby terminating the surface. The etching can be performed using an etching solution containing F⁻, and for example, a method using a mixed solution of lithium fluoride and hydrochloric acid, a method using hydrofluoric acid, or the like may be used. Thereafter, the layer separation (delamination, separating multilayer MXene into single-layer MXene) of MXene may be promoted by any appropriate post-treatment (for example, ultrasonic treatment, handshaking, or the like) as appropriate.

MXenes whose above formula MₘKₙ is expressed as below are known:

Sc₂C, Ti₂C, Ti₂N, Zr₂C, Zr₂N, Hf₂C, Hf₂N, V₂C, V₂N, Nb₂C, Ta₂C, Cr₂C, Cr₂N, Mo₂C, Mo_{1.3}C, Cr_{1.3}C, (Ti,V)₂C, (Ti,Nb)₂C, W₂C, W_{1.3}C, Mo₂N, Nb_{1.3}C, Mo_{1.3}Y_{0.6}C (in the above formula, “1.3” and “0.6” mean about 1.3 (=4/3) and about 0.6 (=2/3), respectively),

Ti₃C₂, Ti₃N₂, Tia (CN) Zr₃C₂, (Ti,V)₃C₂, (Ti₂Nb) C₂, (Ti₂Ta) C₂, (Ti₂Mn) C₂, Hf₃C₂, (HfV) C₂, (Hf₂Mn) C₂, (V₂Ti) C₂, (Cr₂Ti) C₂, (Cr₂V) C₂, (Cr₂Nb) C₂, (Cr₂Ta) C₂, (Mo₂Sc) C₂, (Mo₂Ti) C₂, (Mo₂Zr) C₂, (Mo₂Hf) C₂, (Mo₂V) C₂, (Mo₂Nb) C₂, (Mo₂Ta) C₂, (W₂T) C₂, (W₂Zr) C₂, (W₂Hf) C₂,

Ti₄N₃, V₄C₃, Nb₄C₃, Ta₄C₃, (Ti,Nb)₄C₃, (Nb, Zr)₄C₃, (Ti₂Nb₂) C₃, (Ti₂Ta₂) C₃, (V₂Ti₂) C₃, (V₂Nb₂) C₃, (V₂Ta₂) C₃, (Nb₂Ta₂) C₃, (Cr₂Ti₂) C₃, (Cr₂V₂) C₃, (Cr₂Nb₂) C₃, (Cr₂Ta₂) C₃, (Mo₂Ti₂) C₃, (Mo₂Zr₂) C₃, (Mo₂Hf₂) C₃, (Mo₂V₂) C₃, (Mo₂Nb₂) C₃, (Mo₂Ta₂) C₃, (W₂Ti₂) C₃, (W₂Zr₂) C₃, (W₂Hf₂)C₃, (Mo_{2.7}V_{1.3})C₃ (in the above formula, “2.7” and “1.3” mean about 2.7 (=8/3) and about 1.3 (=4/3), respectively).

Typically, in the above formula, M can be titanium or vanadium and X can be a carbon atom or a nitrogen atom. For example, the MAX phase is Ti₃AlC₂ and MXene is Ti₃C₂Tₓ (in other words, M is Ti, X is C, n is 2, and m is 3).

It is noted, in the present invention, MXene may contain remaining A atoms at a relatively small amount, for example, at 10 mass % or less with respect to the original amount of A atoms. The remaining amount of A atoms can be preferably 8 mass % or less, and more preferably 6 mass % or less. However, even if the remaining amount of A atoms exceeds 10 mass %, there may be no problem depending on the use and conditions of use of the paste (and the conductive film obtained thereby).

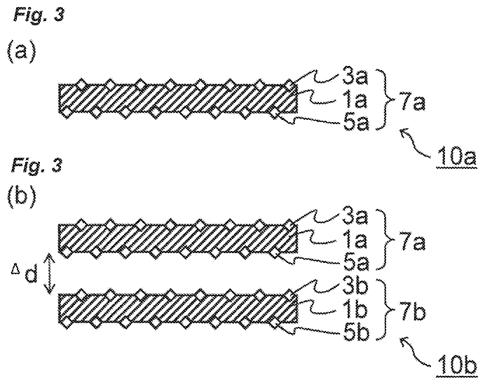

As schematically illustrated in FIGS. 3(a) and 3(b), the MXene (particles) 10 synthesized in this way can be a layered material containing one or plural MXene layers 7a, 7b (as examples of the MXene (particles) 10, FIG. 3(a) illustrates MXene 10a of one layer, and FIG. 3(b) illustrates MXene 10b of two layers, but is not limited to these examples). More specifically, the MXene layers 7a, 7b have layer bodies (MₘXₙ layers) 1a, 1b represented by MₘXₙ, and modifiers or terminals T 3a, 5a, 3b, 5b exist on the surfaces of the layer bodies 1a, 1b (more specifically, on at least one of two surfaces, facing each other, of each layer). Therefore, the MXene layers 7a, 7b are also represented by “MₘXₙTₓ”, wherein x is any number. MXene 10 may be: one that exists as one layer obtained by such MXene layers being separated from one another (single-layer structure illustrated in FIG. 3(a), so-called single-layer MXene 10a); a laminate made of a plurality of MXene layers being stacked to be apart from each other (multilayer structure illustrated in FIG. 3(b), so-called multilayer MXene 10b); or a mixture thereof. MXene 10 can be particles (which can also be referred to as powders or flakes) as a collective entity composed of the single-layer MXene 10a and/or the multilayer MXene 10b. In the present embodiment, MXene 10 is preferably particles (which can also be referred to as nanosheets), most of which are composed of the single-layer MXene 10a. In the case of the multilayer MXene, two adjacent MXene layers (for example, 7a and 7b) may not necessarily be completely separated from each other, but may be partially in contact with each other.

Although not limiting the present embodiment, the thickness of each layer of MXene (which corresponds to the MXene layers 7a, 7b) is, for example, 0.8 nm to 5 nm, and particularly 0.8 nm to 3 nm (which can vary mainly depending on the number of M atom layers included in each layer), and the maximum dimension in a plane (two-dimensional sheet plane) parallel to the layer is, for example, 0.1 μm to 200 μm, and particularly 1 μm to 40 μm. When the MXene is a laminate (multilayer MXene), for each laminate, an interlayer distance (alternatively, a void dimension, indicated by Δd in FIG. 3(b)) is, for example, 0.8 nm to 10 nm, particularly 0.8 nm to 5 nm, and more particularly about 1 nm. The total number of layers may be 2 or more, and is, for example, 50 to 100,000, particularly 1,000 to 20,000. The thickness in the lamination direction is, for example, 0.1 μm to 200 μm, particularly 1 μm to 40 μm. The maximum dimension in a plane (two-dimensional sheet plane) perpendicular to the lamination direction is, for example, 0.1 μm to 100 μm, and particularly 1 μm to 20 μm. Note that these dimensions can be obtained as a number average dimension (for example, a number average of at least 40) based on a photograph of a scanning electron microscope (SEM), a transmission electron microscope (TEM) photograph, or an atomic force microscope (AFM) or a distance in a real space calculated from a position on a reciprocal lattice space of a (002) plane measured by an X-ray diffraction (XRD) method.

The type of metal constituting the metal particles 11A or the sintered metal 11B is not particularly limited. The electrode or wiring of the present embodiment may contain one or more elements selected from the group consisting of Ag, Sn, Pt, Ni, Cu, Au, or Zn, as metal particles 11A or the sintered metal 11B. These elements are elements that can cause ion migration. When these elements are contained, particularly when Ag is contained, the ion migration suppression effect is sufficiently exhibited. When the metal particles 11A or the sintered metal 11B are formed of one or more elements selected from the group consisting of Ag, Sn, Pt, Ni, Cu, Au, or Zn, particularly when the metal particles are formed of Ag, the ion migration suppression effect is sufficiently exhibited.

The size of the metal particles 11A is not particularly limited, but for example, an average particle diameter (D50) measured by a laser diffraction/scattering method is preferably in a range of 0.1 μm to 100 μm.

A content of the particles of the layered material including one or plural layers is 0.1 mass % to 20 mass % with respect to the metal particles or the sintered metal. When the content of the particles of the layered material is 0.1 mass % or more with respect to the metal particles or the sintered metal, the ion migration suppression effect is further exhibited, which is preferable. The content is more preferably 1 mass % or more, and still more preferably 3 mass % or more. On the other hand, the content is preferably 20 mass % or less, more preferably 15 mass % or less, and still more preferably 10 mass % or less from the viewpoint of ease of processing into an electrode or wiring and securing conductivity.

The resin 12 in the electrode or wiring 20A is not limited, and may be a thermosetting resin or a thermoplastic resin. Examples thereof include an acrylic resin, a fluororesin such as polytetrafluoroethylene, a vinyl resin such as polyvinyl chloride, an epoxy resin, polyurethane, a melamine resin, a phenol resin, polyester such as polyethylene terephthalate, polyamide, and polyether.

The ratio of the resin in the composite material constituting the electrode or wiring 20A is, for example, more than 0 mass %, preferably 2 mass % or more in order to exhibit a function as a binder, and on the other hand, is preferably 25 mass % or less, and more preferably 12 mass % or less from the viewpoint of ensuring conductivity.

Examples of the “electrode” include an internal electrode, an external electrode, a pad electrode, a wiring electrode, a ground (reference potential) electrode, a shield pattern, and the like in an electronic component or a circuit board, in which the ion migration failure may occur. Examples of the “wiring” include a signal line forming a circuit pattern, a coil pattern, and an interlayer connection conductor (via conductor).

As an aspect in which the ion migration may occur, depending on the atmosphere such as humidity, when the distance between the electrodes is more than 0 mm and, for example, 6 mm or less, the distance between the wirings is more than 0 mm and, for example, 1 mm or less, liquid may be present between the electrodes and between the wirings. That is, the electrode and the wiring may be present in the atmosphere in which a small amount of liquid exists in addition to being present in the liquid. The air in which a small amount of liquid is present includes, for example, a case where humidity in the air is high and a case where sweat which is a liquid is present on the skin surface of a person. The electrode or wiring of the present embodiment can more effectively suppress ion migration in the atmosphere where a small amount of liquid exists.

### Embodiment 2: Electrode Pair

In the electrode pair in the embodiment of the present invention, the electrode according to the embodiment of the present invention is used as at least one of an anode and a cathode, whereby ion migration can be effectively suppressed even under high humidity, and an electrode pair excellent in conductivity can be realized.

The electrode pair including in the embodiment of the present invention specifically includes:

an anode; and

a cathode,

wherein at least one of the anode and the cathode include particles of a layered material including one or plural layers, and

metal particles or sintered metal,

the one or plural layers includes a layer body represented by:

MₘXₙ

wherein M is at least one metal of Group 3, 4, 5, 6, or 7,

X is a carbon atom, a nitrogen atom, or a combination thereof,

n is 1 to 4, and

m is more than n and 5 or less, and

a modifier or terminal T exists on a surface of the layer body, wherein T is at least one selected from the group consisting of a hydroxyl group, a fluorine atom, a chlorine atom, an oxygen atom, or a hydrogen atom.

At least one of the anode and the cathode contains one or more elements selected from the group consisting of Ag, Sn, Pt, Ni, Cu, Au, or Zn. These elements are elements that can cause ion migration. When these elements are contained, particularly when Ag is contained, the ion migration suppression effect is sufficiently exhibited. When at least one of the anode and the cathode are formed of one or more elements selected from the group consisting of Ag, Sn, Pt, Ni, Cu, Au, or Zn, particularly when the metal particles are formed of Ag, the ion migration suppression effect is sufficiently exhibited. When at least one of the anode and the cathode contains MXene particles, the metal particles or sintered metal contained together are not particularly limited. Thus, the metal particles or sintered metals that can be contained in the anode and the cathode may be the same as or different from each other.

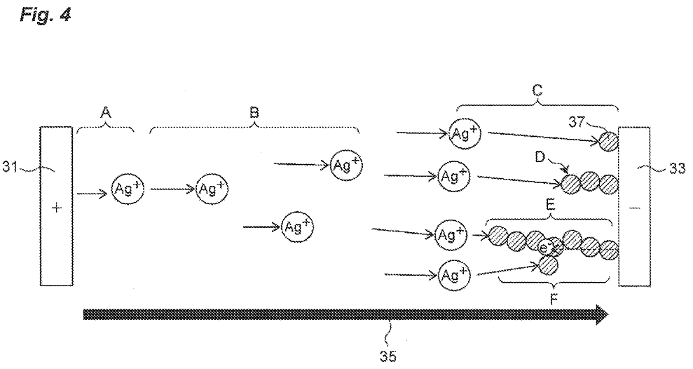

For example, Ag ion migration is considered to occur as schematically illustrated in FIG. 4. That is, as shown in A of FIG. 4, Ag⁺ as a metal ion is eluted from the anode 31, and as shown in B of FIG. 4, Ag⁺ moves between the electrodes from the anode (positive electrode) 31 to the cathode (negative electrode) 33. An arrow 35 indicates a direction of an electric field. Then, as shown in C of FIG. 4, the metal ion Ag⁺ arrives at the cathode 33 and precipitates as the metal Ag 37. At the time of precipitation, as shown in D of FIG. 4, it is easy to precipitate at a tip of the branch due to a shielding effect. In addition, when the crystal grows in a branch shape as shown in E of FIG. 4 and the branch grows while electrons are supplied from the cathode, it is considered that the crystal may also precipitate from the middle of the branch as shown in F of FIG. 4.

In the electrode pair according to the present embodiment, as shown in A of FIG. 4, since MXene suppresses the metal from being converted into the metal ions by extracting electrons from the metal at the anode (positive electrode), metal ions that cause ion migration are not generated, and ion migration is suppressed. This is considered to be due to MXene's electrons being extracted instead of the metal, that is, MXene functioning as a reducing agent.

In the electrode pair according to the present embodiment, as shown in C of FIG. 4, MXene prevents metal ions having moved to the cathode (negative electrode) 33 from receiving electrons, so that metal (metal Ag 37 in FIG. 4) is not deposited on the cathode 33, and ion migration is suppressed. This is considered to be because MXene receives electrons instead of metal ions, that is, functions as an oxidant.

The reason why the ion migration is suppressed in the electrode pair in the present embodiment is not limited thereto, and other mechanisms such as not moving metal ions from the anode to the cathode can be considered.

MXene, which is a two-dimensional layered compound, has a characteristic of high conductivity and also has an oxidation-reduction action (electron transfer). This oxidation-reduction action is considered to be effective in suppressing ion migration.

Therefore, in an electrode pair having an anode and a cathode, at least one of the electrodes constituting the anode and the cathode preferably contains MXene.

The distance between the anode and the cathode is, for example, more than 0 μm and, for example, 6 mm or less as an aspect in which the ion migration can occur, depending on the atmosphere such as humidity. These anode and cathode may be present in the liquid or in the atmosphere in which a small amount of liquid is present. The air in which a small amount of liquid is present includes, for example, a case where humidity in the air is high and a case where sweat which is a liquid is present on the skin surface of a person. The electrode or wiring of the present embodiment can more effectively suppress ion migration in the atmosphere where a small amount of liquid exists.

### Embodiment 3: Method for Producing Electrode or Wiring

Hereinafter, a method for producing an electrode or wiring in the embodiment of the present invention will be described in detail, but the present invention is not limited to such an embodiment.

The method for producing an electrode or wiring of the present embodiment (first producing method) includes

(a1) kneading particles of a predetermined layered material, metal particles, and a resin to prepare a mixture, wherein a blending ratio of the particles of the layered material in the mixture is set to 0.1 mass % to 20 mass % with respect to the metal particles, and

(b1) drying the mixture to obtain an electrode or wiring.

The method for producing another electrode or wiring of the present embodiment (second producing method) includes

(a2) kneading a formulation containing particles of a predetermined layered material and metal particles to prepare a mixture, wherein a blending ratio of the particles of the layered material in the mixture is set to 0.1 mass % to 20 mass % with respect to the metal particles,

(b2) molding and drying the mixture to obtain a molded product, and

(c) firing the molded product at a sinterable temperature. Hereinafter, each step of the first producing method and the second producing method will be described in detail.

Step (a1) of First Producing Method

The particles described in Embodiment 1 are used as particles of a predetermined layered material, that is, particles of a layered material including one or more layers. The materials described in Embodiment 1 can also be used as the metal particles and the resin. As the metal particles and the resin, a metal paste in which these are mixed in advance can be used.

The blending ratio of the particles of the layered material in the mixture is 0.1 mass % to 20 mass % with respect to the metal particles. The reason for setting the upper and lower limit values and the preferable upper and lower limit values are as described in Embodiment 1.

The kneading method is not particularly limited, and examples thereof include stirring with a centrifugal stirrer, kneading using a three-roll mill, and dispersion treatment. In the kneading, when the fluidity is reduced, an organic solvent that can be removed in the subsequent drying step, for example, diethylene glycol monobutyl ether acetate used in examples, may be added.

Step (b1) of First Producing Method

The mixture is dried to obtain an electrode or wiring. The mixture can be molded into a molded product in the shape of an electrode or wiring before drying, but the molding method is not particularly limited. For example, the mixture may be applied to an object to be applied such as a substrate. The coating method is not limited and examples thereof include a spray coating method in which spray coating is performed using a nozzle such as a one-fluid nozzle, a two-fluid nozzle, or an air brush, a slit coating method using a table coater, a comma coater, or a bar coater, a screen printing method, a metal mask printing method, and a coating method by spin coating, dip coating, or dropping. The object to be applied may be appropriately employed as a printed circuit board, a metal substrate, a resin substrate, a laminated electronic component, a metal pin, a metal wire, or the like depending on the application.

Next, drying is performed. The drying condition depends on the shape and size of the molded mixture, and for example, the drying is performed in a range of 60° C. or higher and 200° C. or lower for 10 minutes to 120 minutes.

The coating and drying may be repeated a plurality of times as necessary until a film having a desired thickness is obtained.

Step (a2) of Second Producing Method

The particles described in Embodiment 1 are used as particles of a predetermined layered material, that is, particles of a layered material including one or more layers. The materials described in Embodiment 1 can also be used as the metal particles. As the metal particles, for example, an average particle diameter (D50) measured by a laser diffraction/scattering method is preferably in a range of 1 nm to 200 μm. The mixture may include a binder that can be removed by subsequent firing so as to be easily kneaded.

The blending ratio of the particles of the layered material in the mixture is 0.1 mass % to 20 mass % with respect to the metal particles. The reason for setting the upper and lower limit values of the blending ratio and the preferable upper and lower limit values are as described in Embodiment 1.

The kneading method is not particularly limited, and examples thereof include a method for performing mixing and dispersion using a three-roll mill.

Step (b2) of Second Producing Method

The mixture is molded and dried to obtain a molded product. The molding method is not particularly limited, and molding may be performed, for example, by applying the mixture to an object to be applied such as a substrate. The coating method is not limited and examples thereof include a spray coating method in which spray coating is performed using a nozzle such as a one-fluid nozzle, a two-fluid nozzle, or an air brush, a slit coating method using a table coater, a comma coater, or a bar coater, a screen printing method, a metal mask printing method, and a coating method by spin coating, dip coating, or dropping. The object to be applied may be appropriately employed as a printed circuit board, a metal substrate, a resin substrate, a laminated electronic component, a metal pin, a metal wire, or the like depending on the application.

The drying condition depends on the shape and size of the molded product, and for example, the drying is performed in a range of 60° C. or higher and 200° C. or lower for 10 minutes to 120 minutes.

Step (c) of Second Producing Method

The molded product is fired at a sinterable temperature. The sinterable temperature may be determined depending on the metal species within a range of, for example, approximately 150° C. or higher and 800° C. or lower. The firing time may be determined according to the shape and size of the molded product. The atmosphere during firing is not particularly limited. For the purpose of removing the binder and the like, the atmosphere during firing can be appropriately adjusted to an inert atmosphere, an oxidizing atmosphere, or a reducing atmosphere.

Although the electrode or wiring, the electrode pair, and the method for producing the electrode or wiring in the embodiment of the present invention has been described in detail above, various modifications are possible. It should be noted that the electrode or wiring of the present invention may be produced by a method different from the producing method in the above-described embodiment.

### EXAMPLES

### Example 1

Preparation of MAX Particles

TiC powder, Ti powder, and Al powder (all manufactured by Kojundo Chemical Laboratory Co., Ltd.) were placed in a ball mill containing zirconia balls at a molar ratio of 2:1:1 and mixed for 24 hours. The obtained mixed powder was fired in an Ar atmosphere at 1350° C. for 2 hours. The sintered body (block-shaped MAX) thus obtained was pulverized with an end mill to a maximum dimension of 40 μm or less. In this way, Ti₃AlC₂ particles were obtained as MAX particles.

Preparation of MXene Clay and MXene Powder

1 g of the Ti₃AlC₂ particles (powder) prepared by the above method was weighed, added to 10 mL of 9 mol/L hydrochloric acid together with 1 g of LiF, stirred with a stirrer at 35° C. for 24 hours, and a solid-liquid mixture (suspension) containing a solid component derived from the Ti₃AlC₂ powder was obtained. An operation of separating and removing a supernatant liquid by washing with pure water and decantation using a centrifuge (remaining sediment excluding the supernatant is washed again) was repeated about 10 times to obtain a clay-like substance (clay) as a precipitate. As a result, a Ti₃C₂Tₓ-water dispersion clay was obtained as a MXene clay. The aqueous dispersion clay was freeze-dried and pulverized using a mill manufactured by IKA Japan K.K to obtain a MXene powder.

7 mass % (when dried) of the MXene powder relative to the metal particles was mixed in Ag paste (manufactured by TAIYO HOLDINGS CO., LTD., trade name: ELEPASTE TR70901, containing 10% to 20% of a copolymer resin as a resin), and the mixture was stirred with a centrifugal stirrer at 9,000 rpm for 90 seconds. When the viscosity became high and the fluidity was lost, a solvent (diethylene glycol monobutyl ether acetate) was appropriately added.

Thereafter, a dispersion treatment of the MXene-containing Ag paste was performed using a three-roll machine. The rotation speed of the roll was 230 rpm, and the dispersion conditions were as follows: 2 passes between rolls having a gap of 50 μm, then 2 passes between rolls having a gap of 20 μm, and finally 2 passes between rolls having a gap of 10 μm to obtain a paste of a mixture.

Using a metal mask and a rubber squeegee, the paste of the mixture was manually printed on two substrates to obtain a molded product of a pair of counter electrodes of an anode and a cathode with an interval of 1 mm. The molded product was dried at 140° C. for 30 minutes to obtain a pair of counter electrodes of an anode and a cathode as samples for ion migration evaluation. A total of two samples for ion migration evaluation produced by the same producing method were prepared. In this example, the paste of the mixture containing MXene is printed on both the anode and the cathode, but the same effect can be obtained even when the paste of the mixture containing MXene is printed on one of the anode and the cathode.

As a comparative example, a pair of counter electrodes of an anode and a cathode prepared in the same manner as described above except that MXene was not added was obtained as a sample for evaluation of ion migration. A total of two pair of counter electrodes prepared by the same producing method were prepared.

[Evaluation of Conductivity]

The resistance value of the counter electrode was measured with a tester. Specifically, the resistance between two points was measured while the tester terminals were kept at a constant interval and brought into contact with each counter electrode. Since the resistance value changes depending on the interval distance, the interval was made constant in each measurement. The results of the electrode resistance values of the two counter electrodes of the example and the two counter electrodes of the comparative example are shown in Table 1.

TABLE 1

| | Comparative Example | Example |
|---|---|---|
| | (only Ag) | (MXene + Ag) |
| N1 | 0.000 Ω | 0.000 Ω |
| N2 | 0.000 Ω | 0.000 Ω |

From Table 1 above, the resistance value of the electrode of the example formed using the mixture containing the Ag paste and MXene was the same as the resistance value of the electrode of the comparative example formed only of the Ag paste, and the same conductivity as in the case of only Ag was maintained.

[Evaluation of Ion Migration Suppression Effect]

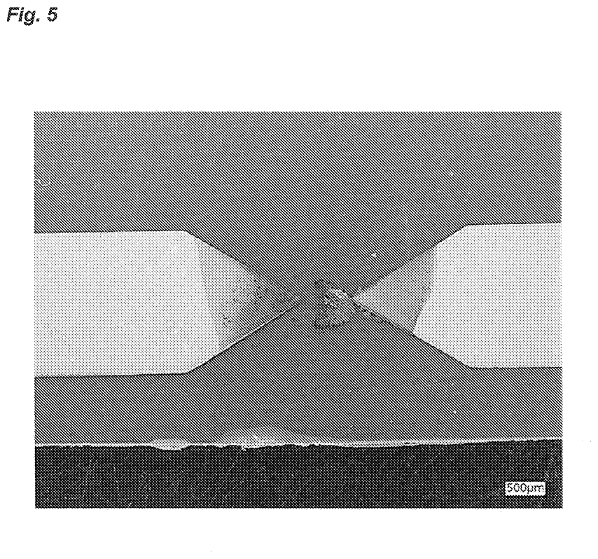

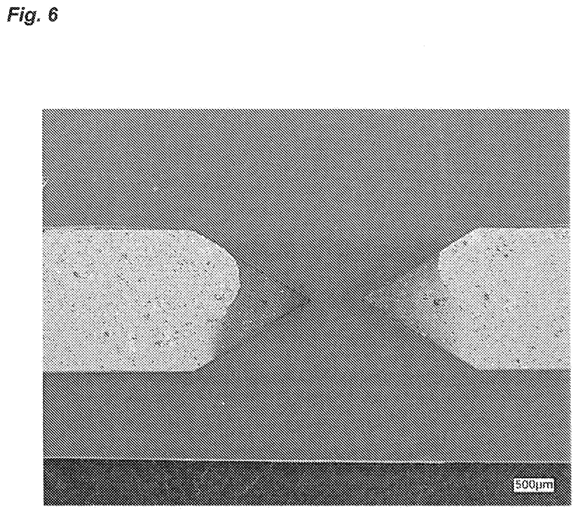

A positive electrode and a negative electrode of a DC power supply were sandwiched between alligator clips on the counter electrode to form an evaluation circuit. After ion-exchanged water for the acceleration test was dropped to a portion of the counter electrode at an interval of 1 mm, 3 V was applied to the evaluation circuit, and a state after 7 minutes was photographed. The results are shown in Tables 5 and 6. FIG. 5 is a photograph in the case of only Ag paste (No MXene, Comparative Example), and FIG. 6 is a photograph in the case of Ag paste+MXene. As illustrated in FIG. 5, in the case of only the Ag paste (without MXene), silver dendrite was generated in the cathode (negative electrode), and ion migration was generated. On the other hand, as illustrated in FIG. 6, in the case of Ag paste+MXene, no dendrite was observed, and ion migration did not occur. Incidentally, the tip of the anode (positive electrode) in FIG. 6 became black, and as a result of separate confirmation, this black substance was silver oxide. From this, it was found that silver contained in the anode (positive electrode) was eluted as silver ions. Although the silver ions move to the negative electrode side, it is considered that the presence of MXene in the cathode can prevent the ion migration failure.

### Example 2

A Ti₃C₂Tₓ-aqueous dispersion clay was freeze-dried in the same manner as in Example 1 described above, and a MXene powder, an Ag powder (size: 1 μm), and an acrylic resin varnish obtained by pulverizing the clay using a mill manufactured by IKA Japan K.K were mixed so as to be 1.9 mass %, 55.7 mass %, and 42.4 mass %, respectively, and mixed in a mortar. Thereafter, the mixture was kneaded with a three-roll mill. The conditions of the kneading with the 3-roll mill were that the gap between the rolls was 10 μm and the peripheral speed of the rolls was 230 rpm. The obtained paste was printed on a substrate through a metal mask matching the electrode shape, heated in an oven at 80° C. for 30 minutes, and dried. Thereafter, the mixture was heated to 750° C. at a heating rate of 10° C./min in a furnace in an Ar atmosphere. After keeping the temperature at 750° C. for 1 hour, it was cooled to obtain the electrode of the present invention. The atmosphere in the furnace was changed from the Ar atmosphere to an oxidizing atmosphere or a reducing atmosphere during heating in order to sufficiently remove the resin component.

Since the electrode obtained in this example also contains predetermined MXene similarly to the electrode according to example of Example 1, it is considered that the conductivity is high and the ion migration failure can be prevented.

### Example 3

Preparation of MAX Particles and Preparation of MXene Powder

MAX particles and MXene powder were prepared in the same manner as in Example 1.

In a Cu paste (manufactured by NOF CORPORATION, trade name: CP-100D, containing a thermosetting resin as a resin in an amount of 10% to 20%), 0.75 mass % (at the time of drying) of the MXene powder with respect to the metal particles was mixed, and the mixture was manually stirred to obtain a mixture paste.

Using a metal mask and a rubber squeegee, the paste of the mixture was manually printed on each of two PET films previously annealed at 150° C. for 30 minutes to obtain a molded product of a pair of counter electrodes of an anode and a cathode with an interval of 1 mm. The molded product was dried at 150° C. for 30 minutes to obtain a pair of counter electrodes of an anode and a cathode as samples for ion migration evaluation.

As a comparative example of Example 3, a pair of counter electrodes of an anode and a cathode prepared in the same manner as described above except that MXene was not added was obtained as a sample for evaluation of ion migration.

[Evaluation of Conductivity]

The resistance value of the counter electrode was measured with a tester. Specifically, the resistance between two points was measured while the tester terminals were kept at a constant interval and brought into contact with each counter electrode. Since the resistance value changes depending on the interval distance, the interval was made constant in each measurement. The results of the electrode resistance values of examples and comparative examples were all 0.000Ω.

From the results of evaluating the conductivity, the resistance value of the electrode of the example formed using the mixture containing the Cu paste and MXene was the same as the resistance value of the electrode of the comparative example formed only of the Cu paste, and the same conductivity as in the case of only Cu was maintained.

[Evaluation of Ion Migration Suppression Effect]

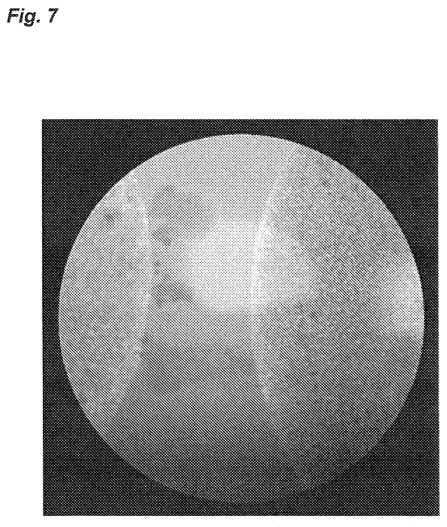

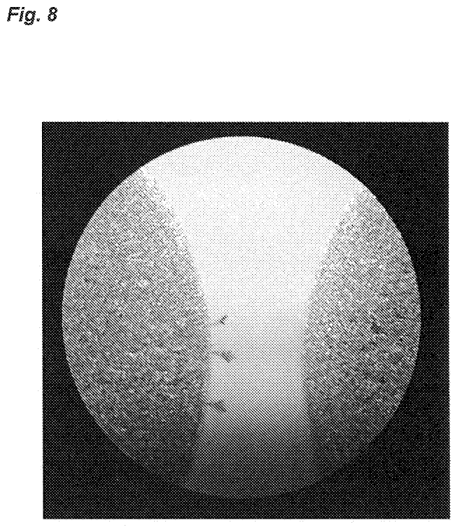

A positive electrode and a negative electrode of a DC power supply were sandwiched between alligator clips on the counter electrode to form an evaluation circuit. After ion-exchanged water for the acceleration test was dropped to a portion of the counter electrode at an interval of 1 mm, 3 V was applied to the evaluation circuit, and a state after 8 minutes was photographed. The results are shown in Tables 7 and 8. FIG. 7 is a photograph in the case of only Cu paste (No MXene, Comparative Example), and FIG. 8 is a photograph in the case of Cu paste+MXene. As illustrated in FIG. 7, in the case of only the Cu paste (without MXene), black dendrite was generated in the cathode (negative electrode), reached the anode (positive electrode) after 8 minutes, and short-circuited. On the other hand, as illustrated in FIG. 8, in the case of the Cu paste+MXene, dendrites were generated, but the growth rate was suppressed, and the effect of suppressing the progress of ion migration was shown. The arrival time at the anode was 24 minutes and 45 seconds.

The electrode or wiring of the present invention may be utilized for any suitable application, and may be particularly preferably used, for example, for one or more of an anode and a cathode in an electrode pair of an electronic component.

Reference Numerals

| 1a, 1b | layer body (MₘXₙ layer) |
|---|---|
| 3a, 5a, 3b, 5b | modifier or terminal T |
| 7a, 7b | MXene layer |
| 10, 10a, 10b | MXene particles (particles of layered material) |
| 11A | metal particle |
| 11B | sintered metal |
| 12 | resin |
| 20A, 20B | electrode or wiring |
| 31 | anode |
| 33 | cathode |
| 35 | direction of electric field |
| 37 | metal Ag |

1. An electrode or wiring of an electronic component or a circuit board comprising:
particles of a layered material including one or plural layers; and
metal particles or sintered metal,
wherein the one or plural layers includes a layer body represented by:
MₘXₙ
wherein M is at least one metal of Group 3, 4, 5, 6, or 7,
X is a carbon atom, a nitrogen atom, or a combination thereof,
n is 1 to 4, and
m is more than n and 5 or less, and
a modifier or terminal T exists on a surface of the layer body, wherein T is at least one selected from the group consisting of a hydroxyl group, a fluorine atom, a chlorine atom, an oxygen atom, or a hydrogen atom.

2. The electrode or wiring according to claim 1, wherein the electrode or wiring is in the form of a composite material containing the particles of the layered material including the one or plural layers, the metal particles, and a resin.

3. The electrode or wiring according to claim 1, wherein the electrode or wiring is in the form of a sintered body containing the particles of the layered material including the one or plural layers, and the sintered metal.

4. The electrode or wiring according to claim 1, wherein M is at least one selected from the group consisting of Ti, Zr, Hf, V, Nb, Ta, Cr, Mo, or Mn.

5. The electrode or wiring according to claim 1, wherein the layer body includes at least one selected from the group consisting of Ti₃C₂, Ti₃CN, or Ti₂C.

6. The electrode or wiring according to claim 1, wherein a content of the particles of the layered material including one or plural layers is 0.1 mass % to 20 mass % with respect to the metal particles or the sintered metal.

7. The electrode or wiring according to claim 1, wherein the metal particles or the sintered metal contains one or more elements selected from the group consisting of Ag, Sn, Pt, Ni, Cu, Au, or Zn.

8. An electrode pair of an electronic component or a circuit board comprising:
an anode; and
a cathode,
wherein at least one of the anode and the cathode include particles of a layered material including one or plural layers, and metal particles or sintered metal,
the one or plural layers includes a layer body represented by:
MₘXₙ
wherein M is at least one metal of Group 3, 4, 5, 6, or 7,
X is a carbon atom, a nitrogen atom, or a combination thereof,
n is 1 to 4, and
m is more than n and 5 or less, and
a modifier or terminal T exists on a surface of the layer body, wherein T is at least one selected from the group consisting of a hydroxyl group, a fluorine atom, a chlorine atom, an oxygen atom, or a hydrogen atom.

9. The electrode pair according to claim 8, wherein the metal particles or the sintered metal contains one or more elements selected from the group consisting of Ag, Sn, Pt, Ni, Cu, Au, or Zn.

10. The electrode pair according to claim 8, wherein a distance between the anode and the cathode is more than 0 mm and 6 mm or less.

11. The electrode pair according to claim 8, wherein the at least one of the anode and the cathode is in the form of a composite material containing the particles of the layered material including the one or plural layers, the metal particles, and a resin.

12. The electrode pair according to claim 8, wherein the at least one of the anode and the cathode is in the form of a sintered body containing the particles of the layered material including the one or plural layers, and the sintered metal.

13. The electrode pair according to claim 8, wherein M is at least one selected from the group consisting of Ti, Zr, Hf, V, Nb, Ta, Cr, Mo, or Mn.

14. The electrode pair according to claim 8, wherein the layer body includes at least one selected from the group consisting of Ti₃C₂, Ti₃CN, or Ti₂C.

15. The electrode pair according to claim 8, wherein a content of the particles of the layered material including one or plural layers is 0.1 mass % to 20 mass % with respect to the metal particles or the sintered metal.

16. A method for producing an electrode or wiring of an electronic component or a circuit board, the method comprising:
(a1) kneading particles of a layered material including one or plural layers, metal particles, and a resin to prepare a mixture,
the one or plural layers including a layer body represented by:
MₘXₙ
wherein M is at least one metal of Group 3, 4, 5, 6, or 7,
X is a carbon atom, a nitrogen atom, or a combination thereof,
n is 1 to 4, and
m is more than n and 5 or less, and
a modifier or terminal T exists on a surface of the layer body,
wherein T is at least one selected from the group consisting of a hydroxyl group, a fluorine atom, a chlorine atom, an oxygen atom, or a hydrogen atom, and
a blending ratio of the particles of the layered material in the mixture is 0.1 mass % to 20 mass % with respect to the metal particles; and
(b1) drying the mixture to obtain an electrode or wiring.

17. The method according to claim 16, wherein the metal particles contain one or more elements selected from the group consisting of Ag, Sn, Pt, Ni, Cu, Au, or Zn.

18. A method for producing an electrode or wiring of an electronic component or a circuit board, the method comprising:
(a2) kneading a formulation containing particles of a layered material including one or plural layers and metal particles to prepare a mixture,
the one or plural layers including a layer body represented by:
MₘXₙ
wherein M is at least one metal of Group 3, 4, 5, 6, or 7,
X is a carbon atom, a nitrogen atom, or a combination thereof,
n is 1 to 4, and
m is more than n and 5 or less, and
a modifier or terminal T exists on a surface of the layer body,
wherein T is at least one selected from the group consisting of a hydroxyl group, a fluorine atom, a chlorine atom, an oxygen atom, or a hydrogen atom, and
a blending ratio of the particles of the layered material in the mixture is 0.1 mass % to 20 mass % with respect to the metal particles;
(b2) molding and drying the mixture to obtain a molded product; and
(c) firing the molded product at a sinterable temperature.

19. The method according to claim 18, wherein the metal particles contain one or more elements selected from the group consisting of Ag, Sn, Pt, Ni, Cu, Au, or Zn.

20. The electrode or wiring according to claim 1, wherein a distance between the wirings is more than 0 mm and 1 mm or less.
